(19) United States
(12) Patent Application Publication
(10) Pub. No.: US 2022/0319849 A1
(43) Pub. Date: Oct. 6, 2022

(54) MASK PATTERN AND METHOD FOR MANUFACTURING SAME, SEMICONDUCTOR STRUCTURE AND METHOD FOR MANUFACTURING SAME

(71) Applicant: CHANGXIN MEMORY TECHNOLOGIES, INC., Hefei City (CN)

(72) Inventors: Qiang WAN, Hefei (CN); Kangshu Zhan, Hefei (CN); Jun Xia, Hefei (CN); Sen Li, Hefei (CN); Penghui Xu, Hefei (CN); Tao Liu, Hefei (CN)

(21) Appl. No.: 17/498,803

(22) Filed: Oct. 12, 2021

Related U.S. Application Data
(63) Continuation of application No. PCT/CN2021/108538, filed on Jul. 27, 2021.

(30) Foreign Application Priority Data
Mar. 30, 2021 (CN) 202110340696.2

(51) Int. Cl. H01L 21/033; H01L 21/311

(52) U.S. Cl. CPC H01L 21/0337; H01L 21/31144; H01L 21/31116

(57) ABSTRACT

A method for manufacturing a mask pattern includes the following operations. A pattern transfer layer, an etching stopping layer, a sacrificial layer and a hard mask layer that are stacked from bottom up are formed. The hard mask layer and the sacrificial layer are patterned to obtain sacrificial patterns which expose the etching stopping layer. Side wall structures are formed on the side walls of the sacrificial patterns. The sacrificial patterns are removed. Filling layers are formed between the side wall structures, and the etching selection ratio of the side wall structures to the filling layers is greater than 100. The side wall structures are removed to form an initial mask pattern. The etching stopping layer and the pattern transfer layer are etched based on the initial mask pattern to transfer a pattern of the initial mask pattern to the pattern transfer layer to obtain a target mask pattern.

### CROSS-REFERENCE TO RELATED APPLICATIONS

This application is a continuation of International Application No. PCT/CN2021/108538, filed on Jul. 27, 2021, which claims priority to Chinese patent application No. 202110340696.2, filed on Mar. 30, 2021. The disclosures of International Application No. PCT/CN2021/108538 and Chinese patent application No. 202110340696.2 are hereby incorporated by reference in their entireties.

### BACKGROUND

With the rapid development of semiconductor memory technologies, the size of semiconductor memory products is becoming smaller and smaller. However, the market puts forward higher requirements on the storage capacity of the semiconductor memory products. Specifically, for a dynamic random access memory (DRAM), how to manufacture the DRAM with a smaller size and a higher reliability is currently an important subject.

During the manufacturing process of a DRAM, a reverse self-aligned double patterning (RSADP) is required. When manufacturing a mask structure by the RSADP, an organic material layer as a sacrificial pattern is easily etched when removing an oxide layer due to the continuously reduced size of the DRAM and a smaller thickness of the oxide layer used as a side wall. When etching is continuously performed based on a gap formed after removing the side wall, by-products derived from the organic material layer (for example, polymer) generated during the etching process are easy to block the bottoms of trenches which are being etched. The by-products will prevent the proceeding of the etching, so that a subsequent process cannot continue to etch down, thereby resulting in inconsistent depths of the etching groove at different positions.

### SUMMARY

The disclosure relates to the field of integrated circuit manufacturing, in particular to a mask pattern and a method for manufacturing the same, a semiconductor structure and a method for manufacturing the same.

According to some embodiments, a mask pattern and a method for manufacturing the same, a semiconductor structure and a method for manufacturing the same are provided.

A method for manufacturing a mask pattern, including the following operations. A pattern transfer layer, an etching stopping layer, a sacrificial layer and a hard mask layer that are stacked from bottom up are formed. The hard mask layer and the sacrificial layer are patterned to obtain sacrificial patterns, which expose the etching stopping layer. Side wall structures are formed at on the side walls of the sacrificial patterns. The sacrificial patterns are removed. Filling layers are formed between the side wall structures, in which an etching selection ratio of the side wall structures to the filling layers is greater than 100. The side wall structures are removed, so as to form an initial mask pattern. The etching stopping layer and the pattern transfer layer are etched based on the initial mask patterns to transfer the pattern of the initial mask pattern is transferred to the pattern transfer layer to obtain a target mask pattern.

A mask pattern, which is manufactured by the method for manufacturing a mask pattern in any one of the above embodiments.

A method for manufacturing a semiconductor structure, including the following operations. A base is provided. A target mask pattern is formed on the base by the method for manufacturing a mask pattern in any one of the above embodiments. The base is etched based on the target mask pattern, so as to obtain the semiconductor structure.

A semiconductor structure is manufactured by the method for manufacturing a semiconductor structure in any one of the above embodiments.

The above description is only an overview of the technical solution of the disclosure. In order to better understand the technical means of this disclosure, detail description is made below in combination with preferred embodiments and drawings of the disclosure.

### BRIEF DESCRIPTION OF THE DRAWINGS

To better clarify the technical solution of the embodiments of the disclosure, the accompanying drawings required to illustrate the embodiments of the disclosure will be briefly described below. Apparently, the accompanying drawings described below merely illustrate some embodiments of the disclosure. Those ordinarily skilled in the art can obtain other drawings of other embodiments without creative labor on the basis of those drawings.

FIG. 1 is a flowchart of a method for manufacturing a mask pattern according to one embodiment of the disclosure.

FIG. 2 is a structural schematic diagram of a local section of forming a pattern transfer layer, an etching stopping layer, a sacrificial layer and a hard mask layer according to an embodiment of the disclosure.

FIG. 3 is a structural schematic diagram of a local section of forming sacrificial patterns according to an embodiment of the disclosure.

FIG. 4 is a structural schematic diagram of a local section of forming a side wall material layer according to an embodiment of the disclosure.

FIG. 5 is a structural schematic diagram of a local section of forming side wall structures on side walls of the sacrificial patterns according to an embodiment of the disclosure.

FIG. 6 is a structural schematic diagram of a local section of forming side wall structures according to an embodiment of the disclosure.

FIG. 7 is a structural schematic diagram of a local section of forming filling layer material layers according to an embodiment of the disclosure.

FIG. 8 is a structural schematic diagram of a local section of forming a filling layer according to an embodiment of the disclosure.

FIG. 9 is a structural schematic diagram of a local section of forming an initial mask pattern according to an embodiment of the disclosure.

FIG. 10-FIG. 12 are process schematic diagrams of forming a target mask pattern based on an initial mask pattern according to an embodiment of the disclosure.

### DETAILED DESCRIPTION

In order to make the disclosure convenient to understand, the disclosure will be described more comprehensively below with reference to the related drawings. The drawings show preferred embodiments of the disclosure. However, the disclosure may be implemented in various forms and is not limited to the embodiments described herein. Instead, these embodiments are provided to make the contents disclosed in the disclosure be understood more thoroughly and comprehensively.

Unless otherwise defined, all technical and scientific terms used herein have the same meanings as commonly understood by those skilled in the art that the disclosure belongs to. Herein, terms used in the description of the disclosure are only for the purpose of describing specific embodiments and not intended to limit the disclosure. The term “and/or” used herein includes any and all combinations of one or more related items which are listed.

It is to be understood that an element or layer is “on”, “adjacent to”, “connected to”, or “coupled to” another element or layer may refer to that the element or layer is directly on, adjacent to, connected to or coupled to the other element or layer, or there may be an intermediate element or layer. On the contrary, description that an element is “directly on”, “directly adjacent to”, “directly connected to” or “directly coupled to” another element or layer refers to that there is no intermediate element or layer. It is to be understood that, although various elements, components, regions, layers and/or parts may be described with terms first, second, third, etc., these elements, components, regions, layers and/or parts should not be limited by these terms. These terms are used only to distinguish one element, component, region, layer or part from another element, component, region, layer or part. Therefore, a first element, component, region, layer or part discussed below may be represented as a second element, component, region, layer or part without departing from the teaching of the disclosure.

Spatially relational terms such as “below”, “under”, “lower”, “beneath”, “above”, and “upper” may be used herein for convenience of description to describe a relationship between one element or feature and another element or feature illustrated in the figures. It is to be understood that, in addition to the orientation shown in the figures, the spatially relational terms are intended to further include different orientations of devices in use and operation. For example, if the devices in the figures are turned over, elements or features described as being “under” or “beneath” or “below” other elements or features will be oriented to be “above” the other elements or features. Therefore, the exemplary terms “under” and “below” may include both upper and lower orientations. The device may be otherwise oriented (rotated by 90 degrees or in other orientations) and the spatial descriptors used herein may be interpreted accordingly.

The terms used herein are for the purpose of describing specific embodiments only and not intended to limit the disclosure. As used herein, the singular forms of “a”, “an”, and “said/the” are also intended to include plural forms, unless otherwise specified in the context. It is also to be understood that, when terms “consisted of” and/or “comprise/include” are used in this specification, the presence of the features, integers, steps, operations, elements, and/or components is determined, but the presence or addition of one or more other features, integers, steps, operations, elements, components, and/or groups is also possible. As used herein, term “and/or” includes any and all combinations of the related listed items.

Embodiments of the disclosure are described with reference to a cross-section view of a schematic diagram of an ideal embodiment (and an intermediate structure) of the disclosure. Thus, changes from the shown shape caused by, for example, a manufacturing technology and/or tolerance can be expected. Therefore, the embodiments of the disclosure should be not limited in the specific shape of the regions shown herein, but include the shape deviation caused by, for example, manufacturing. The regions shown in the figure are substantially schematic. Their shapes are not intended to show the actual shape of the region of the device and are not intended to limit the scope of the disclosure.

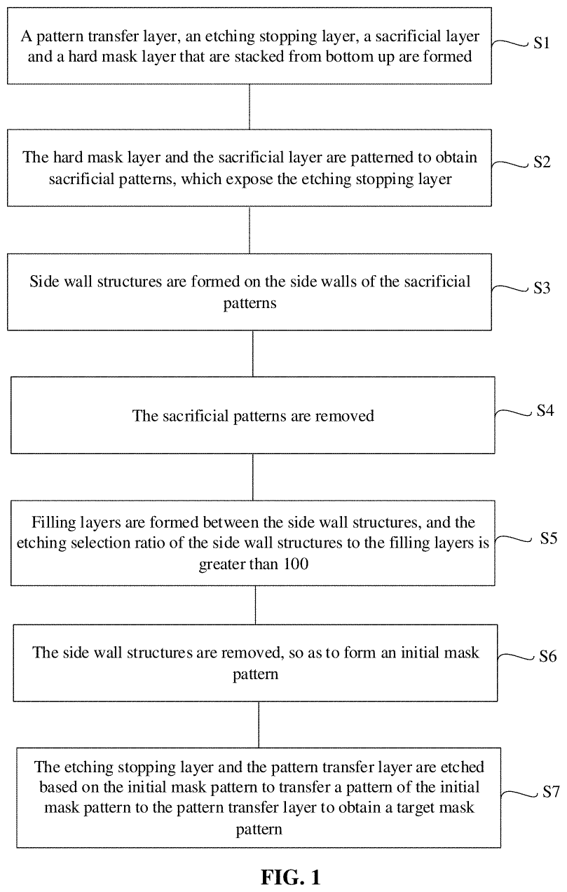

One embodiment of the disclosure provides a method for manufacturing a mask pattern, as shown in FIG. 1, and the method includes the following operations.

At S1, a pattern transfer layer, an etching stopping layer, a sacrificial layer and a hard mask layer that are stacked from bottom up are formed.

At S2, the hard mask layer and the sacrificial layer are patterned to obtain sacrificial patterns, which expose the etching stopping layer.

At S3, side wall structures are formed on the side walls of the sacrificial patterns.

At S4, the sacrificial patterns are removed.

At S5, filling layers are formed between the side wall structures, and an etching selection ratio of the side wall structures to the filling layers is greater than 100.

At S6, the side wall structures are removed, so as to form an initial mask pattern.

At S7, the etching stopping layer and the pattern transfer layer are etched based on the initial mask pattern, so that the pattern of the initial mask pattern is transferred to the pattern transfer layer, and then a target mask pattern is obtained.

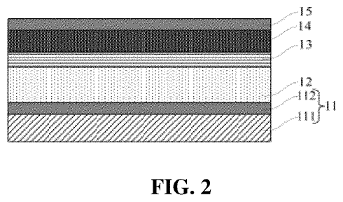

In S1, as shown in FIG. 2, the pattern transfer layer 12, the etching stopping layer 13, the sacrificial layer 14 and the hard mask layer 15 that are stacked from bottom up are formed on a base 11. In which, the pattern transfer layer 12 may include but not limited to an oxide layer, for example, a silicon dioxide layer. The etching stopping layer 13 may include but not limited to a polycrystalline silicon layer. The sacrificial layer 14 may include but not limited to a spin on hard mask (SOH). The hard mask layer 15 may include but not limited to a silicon oxynitride layer.

In one embodiment, the base 11 includes a substrate 111 and a dielectric layer 112 located on the upper surface of the substrate 111. The material of the substrate 111 may include silicon, germanium or silicon germanium, and the dielectric layer 112 may include a silicon oxynitride layer.

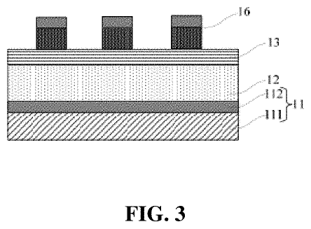

In S2, the hard mask layer 15 and the sacrificial layer 14 are patterned to obtain the sacrificial patterns 16 as shown in FIG. 3. The sacrificial patterns 16 are located on the upper surface of the etching stopping layer 13, and between the sacrificial patterns 16 part of the etching stopping layer 13 is exposed. As an example, the etching selection ratio of the hard mask layer 15 and the sacrificial layer 14 to the etching stopping layer 13 is greater than 1, so that the etching stopping layer 13 cannot be penetrated through, avoiding etching the pattern transfer layer 12 in a process of patterning the hard mask layer 15 and the sacrificial layer 14. Specifically, the etching selection ratio of the hard mask layer 15 and the sacrificial layer 14 to the etching stopping layer 13 may be 2, 5, 10, 20, etc. As shown in FIG. 3, each sacrificial pattern 16 includes an upper layer and a lower layer, namely, each sacrificial pattern 16 includes the hard mask layer 15 reserved after patterning and the sacrificial layer 14 reserved after patterning.

In S3, the side wall structures are formed on the side walls of the sacrificial patterns 16. In one embodiment, forming the side wall structures includes the following operations.

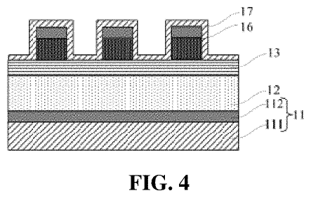

At S31, the side wall material layer 17 is formed on the side walls of the sacrificial patterns 16, the tops of the sacrificial patterns 16 and the exposed surface of the etching stopping layer 13, as shown in FIG. 4.

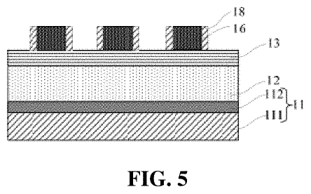

At S32, the side wall material layer 17 located on the tops of the sacrificial patterns 16 and the exposed surface of the etching stopping layer 13 is removed, and the side wall material layer 17 located on the side walls of the sacrificial patterns 16 is reserved, as shown in FIG. 5.

In S31, as shown in FIG. 4, firstly, the side wall material layer 17 may be deposited on the side walls and tops of the sacrificial patterns 16 and the exposed upper surface of the etching stopping layer 13 by adopting the atomic layer deposition process, but it is not limited to this process. The thickness of the side wall material layer 17 may be adjusted according to requirements. In the embodiment, the thickness of the side wall material layer 17 deposited on the side walls of each sacrificial pattern 16 is equal.

As an example, the material of the side wall material layer 17 may include but be not limited to silicon dioxide.

In S32, after forming the side wall material layer 17, the side wall material layer 17 located on the tops of the sacrificial patterns 16 and the side wall material layer 17 located on the surface of the etching stopping layer 13 is removed by an etching process. At the same time, after removing the side wall material layer 17 located on the tops of the sacrificial patterns 16 and the side wall material layer 17 located on the surface of the etching stopping layer 13, the hard mask layer part of a sacrificial pattern 16 may be removed, so as to expose the part of the sacrificial layer 14 that is reserved after patterning. After the side wall material layer 17 in FIG. 4 is subjected to the etching process, the side wall structures 18 located on the side walls of the sacrificial patterns 16 as shown in FIG. 5 are obtained. In the embodiment, the etching selection ratio of the side wall material layer 17 to the etching stopping layer 13 is greater than 1, for example, 10, 20 or 30, such that penetration through the etching stopping layer 13 in the etching process of forming the side wall structures 18 is avoided, thereby avoiding damages to the pattern transfer layer 12.

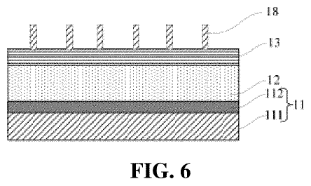

In S4, the sacrificial patterns 16 are removed. Specifically, since the hard mask layer part of each sacrificial pattern 16 is removed in S3, the remaining sacrificial layer part may be removed by adopting a SOH strip process, so as to obtain the side wall structures 18 arranged at intervals as shown in FIG. 6. Herein, the gap distance between the side wall structures 18 may be adjusted by controlling the width of the sacrificial patterns 16.

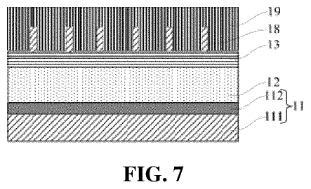

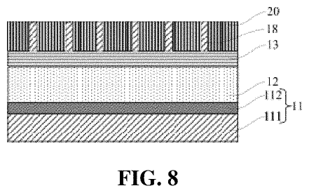

In S5, the filling layers are formed between the side wall structures 18, and the etching selection ratio of the side wall structures to the filling layers is greater than 100. Specifically, the etching selection ratio of the side wall structures 18 to the filling layers may be 110, 150, 200, 250, etc. Specifically, as shown in FIG. 7 and FIG. 8, a filling material layer 19 is formed on the upper surface of the etching stopping layer 13, the filling material layer 19 fills up the gaps between the side wall structures 18 and covers the side wall structures 18, as shown in FIG. 7. And then the filling material layer 19 located on the side wall structures 18 is removed, so as to obtain the filling layers 20. The upper surface of the filling layers 20 is flush with the upper surface of the side wall structures 18, as shown in FIG. 8.

As an example, the filling material layer 19 as shown in FIG. 7 may be formed by adopting a silicon nitride deposition process, for example, an atomic layer deposition process, a chemical vapor deposition process or a physical vapor deposition process.

As an example, the filling layers 20 as shown in FIG. 8 may be formed by adopting a silicon nitride back etching process, for example, a dry etching process or a wet etching process.

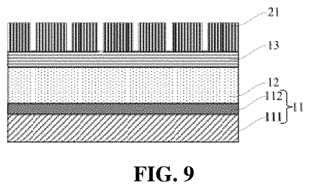

In the embodiment, the etching speed of the side wall structures 18 is over 100 times quicker than that of the filling layers under the same etching condition by setting the etching selection ratio of the side wall structures 18 to the filling layers 20 to be greater than 100. Therefore, when removing the side wall structures 18 in S6, the filling layers 20 are almost not affected by the current etching condition, thereby forming the initial mask patterns 21 as shown in FIG. 9.

As an example, the side wall structures 18 may be removed by a dry etching process in S6, so as to form the initial mask patterns 21. Specifically, an etching gas for removing the side wall structures 18 may be a mixed gas consisted of ammonia gas and nitrogen trifluoride or a mixed gas consisted of hydrofluoric acid and nitrogen trifluoride. The etching temperature may be controlled at 100-1000° C. The etching temperature may be 100-120° C.; for example, the etching temperature may be 100° C., 110° C. or 120° C. Certainly, in other examples, the etching temperature may be greater than 800° C., for example, 800° C., 900° C. or 1000° C., etc. The side wall structures 18 are removed by adopting a gas molecule etching process. Therefore, even if the side wall structures 18 are narrow and the formed side wall gaps are small, a thorough clearing can be implemented.

Optionally, a material of the side wall structures 18 may be silicon oxide, and a material of the initial mask patterns 21 may be silicon nitride. The etching selection ratio of silicon oxide to silicon nitride may be controlled to be greater than 100 by regulating etching process parameters, so that the etching to the initial mask patterns 21 may be reduced when effectively removing the side wall structures 18. Therefore, the by-products (for example, a polymer) generated during the etching process is prevented from being blocked at the tops of the side wall structures 18, thereby avoiding that the etching gas cannot contact with the side wall structures 18, and the proceeding of the etching process and the removing of the side wall structures 18 are affected. At the same time, benefit by the high etching selection ratio of the side wall structures 18 to the initial mask patterns 21, impurities, that are enough to block the gaps formed by the side wall structures 18 and the gaps formed when subsequently forming the target mask pattern by etching, are almost not generated in the etching process, thereby solving the problem that the gaps formed by the side wall structures and the gaps formed when subsequently forming the target mask pattern by etching are blocked by the reaction by-products generated with the proceeding of the etching process in the traditional process.

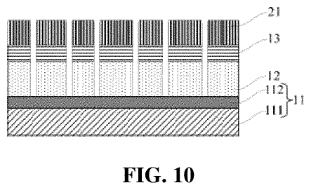

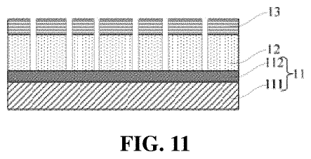

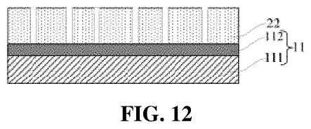

In S7, the pattern transfer layer 12 and the etching stopping layer 13 are etched based on the initial mask pattern 21, so that the pattern of the initial mask pattern 21 is transferred to the pattern transfer layer 12, and then the target mask pattern 22 is obtained. In an embodiment, referring to FIG. 10-FIG. 12, the step includes the following specific operations. The etching stopping layer 13 and the pattern transfer layer 12 are etched based on the initial mask pattern 21, so that the pattern of the initial mask pattern 21 is transferred to the pattern transfer layer 12, as shown in FIG. 10. After that, the initial mask pattern 21 is removed, as shown in FIG. 11. Then the etching stopping layer 13 is removed, as shown in FIG. 12.

Firstly, as shown in FIG. 10, a downwards etching is performed based on the initial mask pattern 21. The part covered by the initial mask pattern 21 is reserved, and the other part not covered by the initial mask pattern 21 is etched to be penetrated until the upper surface of the base.

And then, the initial mask pattern 21 is removed, so as to obtain a semiconductor structure as shown in FIG. 11.

In another embodiment, referring to FIG. 11 and FIG. 12, the specific steps include the following operations. The etching stopping layer 13 and the pattern transfer layer 12 are etched based on the initial mask pattern 21, so that the pattern of the initial mask pattern 21 is transferred to the pattern transfer layer 12. At the same time, the initial mask pattern 21 is removed by etching in the process of etching the etching stopping layer 13 and the pattern transfer layer 12, as shown in FIG. 11. The etching stopping layer 13 is removed, as shown in FIG. 12.

Firstly, as shown in FIG. 11, the downwards etching is performed based on the initial mask pattern 21. The part covered by the initial mask pattern 21 is reserved, and the other part not covered by the initial mask pattern 21 is etched to be penetrated until the upper surface of the base. At the same time, when performing the downwards etching, the initial mask pattern 21 is removed by controlling the etching process, such that the initial mask pattern 21 is just removed by etching when the etching to the pattern transfer layer 12 is completed, and then the semiconductor structure as shown in FIG. 11 is obtained.

As an example, the initial mask pattern 21 may be removed by adopting a dry etching process.

Finally, the etching stopping layer 13 is removed, so as to obtain the target mask patterns 22 as shown in FIG. 12. As an example, the etching gas may be chlorine. The etching temperature is controlled between 30° C. and 70° C., for example, the etching temperature may be 30° C., 40° C., 50° C., 60° C., 70° C., etc.

According to the above method for manufacturing a mask pattern, the etching stopping layer is added, and the initial mask patterns are manufactured on the etching stopping layer. At the same time, the etching selection ratio of the side wall structures to the filling layers is controlled to be greater than 100, so when removing the side wall structures and forming the side wall gaps by etching, the initial mask pattern formed by etching the filling layers is almost not etched. The above method for manufacturing a mask pattern is introduced into a RSADP process, the risk that the gaps are blocked when forming a target mask pattern 22 by continuous etching based on the side wall gaps formed by removing the side walls is reduced.

In one embodiment, the respective etching selection ratios of the side wall structures 18, the hard mask layer 15 and the sacrificial layer 14 to the etching stopping layer 13 are greater than 1, so the etching speeds to the sacrificial layer 14, the hard mask layer 15 and the side wall material layer 17 are respectively greater than the etching speed to the etching stopping layer 13 in a process of manufacturing the side wall structures 18. The etching stopping layer 13 has a blocking effect, which avoids the uneven etching to the surface of the pattern transfer layer 12 caused by etching the pattern transfer layer 12 in advance, so the final formation of the target mask pattern 22 is not affected. Specifically, the respective etching selection ratios of the side wall structures 18, the hard mask layer 15 and the sacrificial layer 14 to the etching stopping layer 13 may be 2, 5, 10, 20 or 30, and so on.

The disclosure further provides a mask pattern, which is manufactured by adopting the method for manufacturing a mask pattern in any one of the above embodiments. The mask pattern obtained by adopting the method for manufacturing a mask pattern in the above embodiments is closer to a preset shape.

Still referring to FIG. 1-FIG. 12, the disclosure further provides a method for manufacturing a semiconductor structure, which includes the following operations. A base 11 is provided. A target mask pattern 22 is formed on the base by adopting the method for manufacturing a mask pattern in any one of the above embodiments. The base 11 is etched based on the target mask pattern 22, so as to obtain the semiconductor structure.

The method for manufacturing a mask pattern in the above embodiment is adopted in a process of manufacturing the target mask patterns 22. An etching stopping layer is introduced, so that the pattern transfer layer is avoided to be etched in the process of forming the initial mask pattern. The sacrificial layer is firstly removed, then the side wall structures are removed after forming the filling layers between the side wall structures, and the etching selection ratio of the side wall structures to the filling layers is controlled to be greater than 100, so as to avoid the risk of blocking the side wall gaps formed after removing the side walls and the risk of blocking the gaps formed by continuously etching based on the gaps formed after removing the side walls.

In an embodiment, the base 11 includes a substrate 111 and a dielectric layer 112 located on the upper surface of the substrate 111, and the target mask pattern 22 is formed on the upper surface of the dielectric layer 112.

The disclosure further provides a semiconductor structure, which is manufactured by adopting the method for manufacturing a semiconductor structure in any one of the above embodiments.

Each technical feature of the abovementioned embodiments may be combined arbitrarily. For simplicity of description, not all possible combinations of each technical feature in the abovementioned embodiments are described. However, as long as there is no contradiction, any combination of these technical features shall fall within the scope recorded in the specification.

The abovementioned embodiments only express some implementation modes of the disclosure, and are specifically described in detail and not thus understood as limits to the patent scope of the disclosure. It is to be pointed out that those of ordinary skill in the art may further make a plurality of transformations and improvements without departing from the concept of the disclosure, and all of these shall fall within the scope of protection of the disclosure. Therefore, the scope of protection of the disclosure should be subject to the appended claims.

1. A method for manufacturing a mask pattern, comprising:
forming a pattern transfer layer, an etching stopping layer, a sacrificial layer and a hard mask layer that are stacked from bottom up;
patterning the hard mask layer and the sacrificial layer to obtain sacrificial patterns, which expose the etching stopping layer;
forming side wall structures on side walls of the sacrificial patterns;
removing the sacrificial patterns;
forming filling layers between the side wall structures, and an etching selection ratio of the side wall structures to the filling layers being greater than 100;
removing the side wall structures, so as to form an initial mask pattern; and
etching the etching stopping layer and the pattern transfer layer based on the initial mask pattern to transfer the pattern of the initial mask pattern to the pattern transfer layer, and to obtain a target mask pattern.

2. The method of claim 1, wherein forming the side wall structures on the side walls of the sacrificial patterns comprises:
forming a side wall material layer on the side walls of the sacrificial patterns, tops of the sacrificial patterns and the exposed surface of the etching stopping layer; and
removing the side wall material layer located on the tops of the sacrificial patterns and the exposed surface of the etching stopping layer, and reserving the side wall material layer located on the side walls of the sacrificial patterns.

3. The method of claim 2, wherein the side wall material layer is formed on the side walls of the sacrificial patterns, the tops of the sacrificial patterns and the exposed surface of the etching stopping layer by adopting an atomic layer deposition process.

4. The method of claim 1, wherein forming the filling layers between the side wall structures comprises:
forming a filling material layer, which fills up gaps between the side wall structures and covers the side wall structures; and
removing the filling material layer located on the side wall structures, so as to obtain the filling layers, and upper surfaces of the filling layers being flush with those of the side wall structures.

5. The method of claim 1, wherein the pattern transfer layer comprises a silicon oxide layer, the etching stopping layer comprises a polycrystalline silicon layer, the sacrificial layer comprises a spin organic hard mask layer, the hard mask layer comprises a silicon oxynitride layer, the side wall structures comprise silicon oxide structures, and the filling layers comprise silicon nitride layers.

6. The method of claim 5, wherein removing the side wall structures to form the initial mask pattern comprises:
removing the side wall structures by adopting a dry etching process, and an etched gas for removing the side wall structures comprising a combination of nitrogen trifluoride and ammonia or hydrofluoric acid.

7. The method of claim 6, wherein an etching temperature for removing the side wall structures is 100-120° C.

8. The method of claim 7, wherein an etching selection ratio of silicon oxide layer to silicon nitride layer is greater than 100.

9. The method of claim 1, wherein said etching the etching stopping layer and the pattern transfer layer based on the initial mask pattern to transfer the pattern of the initial mask pattern to the pattern transfer layer and to obtain the target mask pattern comprises:
etching the etching stopping layer and the pattern transfer layer based on the initial mask pattern, so as to transfer the pattern of the initial mask pattern to the pattern transfer layer;
removing the initial mask pattern; and
removing the etching stopping layer.

10. The method of claim 9, wherein the etching stopping layer is removed by adopting a dry etching process, in which an etching gas for removing the etching stopping layer comprises chlorine, and an etching temperature is 30-70° C.

11. The method of claim 1, wherein the respective etching selection ratios of the side wall structures, the hard mask layer and the sacrificial layer to the etching stopping layer are greater than 1.

12. A mask pattern, which is manufactured by adopting the method for manufacturing a mask pattern of claim 1.

13. A mask pattern, which is manufactured by adopting the method for manufacturing a mask pattern of claim 5.

14. A mask pattern, which is manufactured by adopting the method for manufacturing a mask pattern of claim 6.

15. A mask pattern, which is manufactured by adopting the method for manufacturing a mask pattern of claim 7.

16. A mask pattern, which is manufactured by adopting the method for manufacturing a mask pattern of claim 11.

17. A method for manufacturing a semiconductor structure, comprising:
providing a base;
forming a target mask pattern on the base by adopting the method of claim 1; and
etching the base based on the target mask pattern, so as to obtain the semiconductor structure.

18. The method of claim 17, wherein the base comprises a substrate and a dielectric layer located on an upper surface of the substrate; the target mask pattern is formed on an upper surface of the dielectric layer; the material of the substrate comprises silicon, germanium or silicon germanium, and the dielectric layer comprises a silicon oxynitride layer.

19. A semiconductor structure, which is manufactured by the method of claim 17.

20. A semiconductor structure, which is manufactured by the method of claim 18.
